(19) United States
(12) Patent Application Publication
(10) Pub. No.: US 2011/0037456 A1
(43) Pub. Date: Feb. 17, 2011

(54) Measuring Transducer for Process Instrumentation, and Method for Monitoring the Condition of the Sensor Thereof

(76) Inventors: Eric Chemisky, Soultz sous forets (FR); Thomas Essert, Ostringen (DE); Delphine Meunier, Scheibenhard (FR); Robin Pramanik, Karlsruhe (DE); Martin Spatz, Landau (DE)

Correspondence Address: COHEN, PONTANI, LIEBERMAN & PAVANE LLP, 551 FIFTH AVENUE, SUITE 1210, NEW YORK, NY, 10176, US

(21) Appl. No.: 12/988,766

(22) PCT Filed: Apr. 24, 2009
(86) PCT No.: PCT/EP2009/054958

§ 371 Date: Oct. 26, 2010

(30) Foreign Application Priority Data
Apr. 25, 2008 (DE) 102008020862.0

(51) Int. Cl. G01R 21/14; G01R 19/00

(52) U.S. Cl. 324/105; 324/76.11

(57) ABSTRACT

A measuring transducer for process instrumentation that comprises a sensor for sensing a physical or chemical variable, wherein the sensor includes at least one electrical element embedded in a substrate comprising semiconducting material and is electrically separated therefrom by a blocked PN junction during normal operation. In order to monitor the condition of the sensor, the PN junction is connected in the conducting direction in a test mode, and the electrical property of the PN junction, i.e., the forward voltage, is determined and used to monitor the sensor condition. Additionally, a temperature sensor mounted on the sensor can be monitored by determining, based on the dependence of the forward voltage on the temperature, a comparative value for the temperature sensed by the temperature sensor. If major differences occur, a conclusion can be reached that there is a failure of the sensor, and a corresponding error message can be output over a field bus.

### CROSS-REFERENCE TO RELATED APPLICATIONS

This is a U.S. national stage of International Application No. PCT/EP2009/054958, filed on 24 Apr. 2009. Priority is claimed on German Application No. 10 2008 020 862.0, filed on 25 Apr. 2008. The entire content of both applications are incorporated herein by reference.

### BACKGROUND OF THE INVENTION

1. Field of the Invention

The invention relates to a process instrumentation and, more particularly, to a measuring transducer for process instrumentation, comprising a sensor for detecting a physical or chemical variable and to a method for monitoring the condition of the sensor.

2. Description of the Related Art

In process-related systems, a wide range of field devices for the process instrumentation is used to control processes. Measuring transducers are used to detect process variables, such as temperature, pressure, flow quantity, fill level, density or gas concentration of a medium. Actuators enable the process cycle to be influenced in accordance with a strategy predefined by a control station, for instance, as a function of the detected process variables. A control valve, a heating system or a pump are cited as examples of actuators.

DE 693 09 123 T2 discloses a sensor of a pressure transducer with a laminated substrate. Here, a thin membrane provided with electrical elements and made of silicon is attached above an open chamber. Pressure changes cause the membrane to deflect into and out of the chamber. The displacements invoke changes in an electrical parameter, usually a capacitance or a resistance value, which can be measured and converted into information which corresponds to the pressure. The use of solid-state pressure sensors in a harsh working environment frequently requires a housing, which surrounds the sensor and protects this from direct contact by the medium. To this end, the housing comprises pressure-resistant metal parts, in which one or more measuring chambers are located, which are each covered by a flexible, media-tight membrane, which separates the measuring chambers from the medium and deforms if the pressure of the medium changes. A non-corrosive, inert filling fluid, such as a silicon oil, is present in the measuring chamber between the separating membrane and the sensor membrane and transmits the pressure to be measured to the sensor membrane. Electrical lines, which guide signals from the sensor to external contacts, are routed out of the housing through pressure-tight line ducts and are connected to a control and evaluation facility to evaluate the signals. Here, the control and evaluation facility outputs a measured value to a control station or a programmable logic controller over a field bus, where the measured value corresponds to a respective pressure. No further details of the technical design of the electrical elements which are used to detect the deflections in the sensor membrane caused by the pressure can be inferred from DE 693 09 123 T2.

Generally, sensor elements, which convert physical variables, such as pressure, temperature or gas concentration, into electrical signals, can be attached to a planar substrate. This substrate is then used as a mechanical fastening of the sensitive sensor element on a carrier and also as protection against external influences, such as to improve the electromagnetic compatibility. In particular, with piezoresistive pressure sensors, there is the possibility of attaching the electrical elements to the substrate, embedding these elements in the substrate and doping the substrate in the vicinity of these elements, with an electrical contact existing between the electrical element and the substrate. With a suitable application of a voltage, a PN junction comprising a diode provides for electrical separation of the element and substrate. Here, the electrical properties of the PN junction depend on the substrate material and the doping. A change in the sensor material due to chemical contamination, for instance, may cause changes in the measuring signal and thus in an error in the measured value.

### SUMMARY OF THE INVENTION

It is therefore an object of the present invention to provide a measuring transducer for process instrumentation, in which the condition of a substrate, which supports the electrical elements for generating a measuring signal, can be monitored.

This and other objects and advantages are achieved in accordance with the invention by providing a method and measuring transducer in which monitoring of changes in the condition of the material of the sensor due to, e.g., chemical contamination is performed. Changes of this type were previously not detectable and could result in undetected drift occurrences in the measured value, which is determined and output by the measuring transducer. The possibility of a detection of changes to the sensor is particularly advantageous, because a very high reliability during the measurement of physical or chemical variables is required in an increasing number of measuring transducer applications. This reliability is confirmed by corresponding certifications, e.g., according to International Electrotechnical Committee Standard IEC61508. As a result of the new possibility of monitoring the condition of the sensor, diagnosis measurements on the sensor are no longer required to be restricted to the measurement of the electrical interruption in the electrical elements themselves or in the electrical connecting lines. It is now instead possible to detect changes in the junctions between the electrical elements and the substrate and in the substrate itself.

If the electrical property of the PN junction, which is determined and evaluated to monitor the condition of the sensor, is temperature-dependent, if a temperature sensor is also provided to detect the substrate temperature and if the device for monitoring the condition of the sensor is also configured to determine a first value of the temperature based on the electrical property and to compare this first value with a second value, which is determined with the temperature sensor, a monitoring of the accuracy of the temperature sensor is also advantageously enabled. Temperature sensors are thus frequently integrated into the sensor, in addition to the actual electrical elements provided to generate the measuring signal, because the temperature sensitivity cannot be neglected, especially in the case of sensors with a silicon substrate. With sensors of this type, an error of 2%/10K temperature difference is usual and a faulty measurement of the temperature inevitably results in an error compensation of the measured value determined as a function of the measuring signal. As the measurement of the temperature only previously occurred with the aid of a single temperature sensor, the diagnosis of the circuit used for temperature measurement had to restrict itself to the detection of an interruption in the temperature sensor itself or in the supply lines of the sensor. By contrast, slow drift occurrences could not previously be detected. Due to the dependency of the electrical property of the PN junction on the actual temperature, a comparison value now exists for the temperature measured with the temperature sensor. Consequently, the temperature measurement can be checked for correctness and errors can be detected. It is not necessary to differentiate between errors due to changes in the PN junction or substrate or errors as a result of the temperature sensor, because if one of the errors occurs, an error message can be output by the measuring transducer and a process in which the measuring transducer is used can if necessary be brought into a safe state. A behavior of this type is already deemed to be safe with a certification according to the IEC61508 standard and the sensor is deemed to be 100% diagnosed.

In an advantageous embodiment of the invention, the electrical property of the PN junction is its forward voltage in the conducting direction. This is dependent above all on the temperature and the condition of the materials used, which can subtly change as a result of chemical contamination for instance. Gradually developing errors can thus be easily identified. The forward voltage can be measured, within the framework of a calibration of the sensor using the temperature, for instance, as a changeable parameter and can be stored as a calibration curve in an EEPROM of a microcontroller. The PN junction, the temperature behavior of which is thus known, can assume the function of a calibrated temperature sensor and be used to diagnose the actual temperature sensor.

The measuring transducer with the new facility for monitoring the condition of the sensor can be manufactured with particularly little effort, if the device for monitoring the condition are arranged at least partially in the control and evaluation facility already available.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

With the aid of the drawings, in which exemplary embodiments of the invention are shown, the invention, its embodiments and advantages are described in more detail below, in which:

FIG. 1 is an illustration of the measuring transducer in accordance with an embodiment of the invention; and

FIG. 2 is a flow chart of a method in accordance with an embodiment of the invention.

### DETAILED DESCRIPTION OF THE PREFERRED EMBODIMENTS

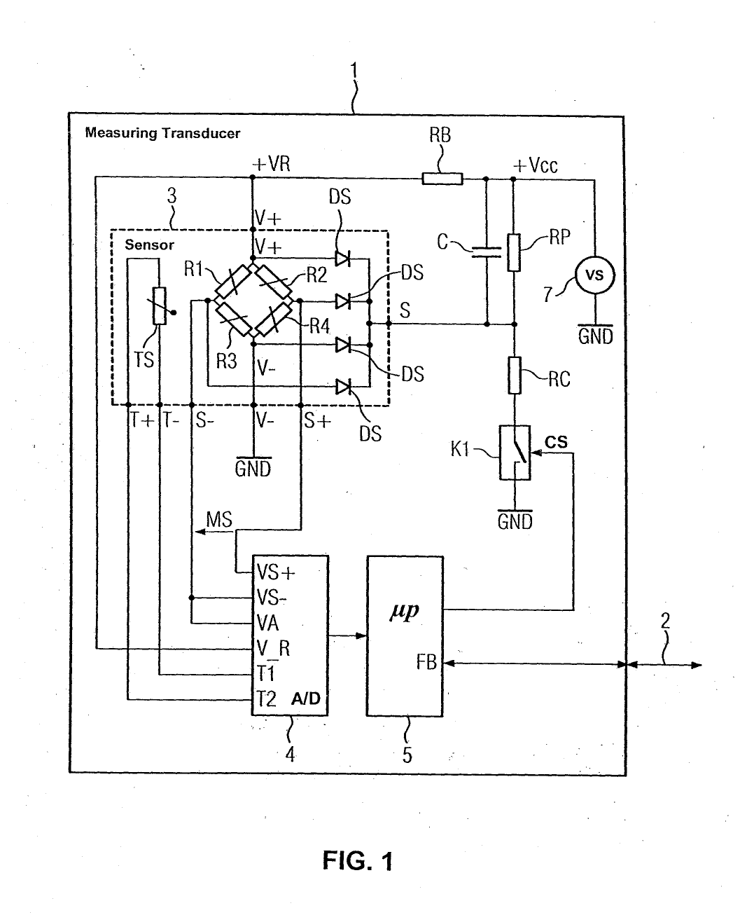

FIG. 1 shows the main electrical configuration of a measuring transducer 1, which is used for process instrumentation and can be connected to a field bus 2 for communication with a superordinate control station in a process-related system. On the one hand, the measuring transducer 1 can be supplied with its operating parameters over the field bus 2, e.g., addresses on the field bus 2 or type of representation of the measured. On the other hand, measured values, such as alarm or status messages, can be output by the measuring transducer over the field bus 2.

A sensor 3 is used to detect a physical or chemical variable, in the exemplary embodiment shown, to thereby detect a pressure. The remaining components of the measuring transducer 1 have the function of a control and evaluation unit, the core of which is formed by an A/D converter 4 and a microcontroller 5. The control and evaluation unit determines a measured value of the physical or chemical variable as a function of a measuring signal MS, which is present at inputs VS+ and VS of the A/D converter 4, and outputs this at an output FB of the microcontroller 5. The sensor 3 contains four pressure-dependent resistors R1, R2, R3 and R4, which are connected to a measuring bridge. The measuring signal MS is measured as a voltage between two connecting points S+ and S−, with the measurement being implemented in a ratiometric fashion relative to a supply voltage between the connecting points V+ and V− of the sensor 3.

The resistors R1 . . . R4 represent electrical elements, which are embedded in a substrate of the sensor 3. To electrically insulate these elements from the substrate, the substrate is doped in the vicinity of the elements so that a diode is produced between the resistors R1 . . . R4, which is indicated in each case by the letters DS in FIG. 1 and which is blocked while performing measurements during normal operation. The diodes DS are thus realized by a PN junction between the electrical elements, i.e., the resistors R1 . . . R4 and the substrate of the sensor 3.

To measure the temperature of the sensor 3, a temperature measuring resistor TS is also located on the substrate, the connecting lines of which are routed to two connecting points T+ and T− of the sensor 3 and are connected to inputs T1 and T2 of the A/D converter 4.

A voltage source 7, which is connected to ground GND, generates a supply voltage +Vcc, which is routed across a resistor RB, which allows the sensor 3 to be monitored for interruption. In this way, a reference voltage +VR is obtained, which is connected to the connection point V+ for supplying the sensor 3 and to an input V_R for a reference voltage of the A/D converter 4 to enable a purely ratiometric measurement.

During normal operation, the A/D converter 4 measures the differential measuring signal MS, which is applied to inputs VS+ and VS− of the A/D transducer 4. Furthermore, the A/D transducer 4 is also able to measure the absolute potential relative to mass at an input VA, which is connected to the connecting point S− of the sensor 3. The input VA is also used to determine the forward voltage of the PN junctions, which are symbolized in FIG. 1 by diodes DS. To measure the forward voltage in the conducting direction of the diodes DS as an electrical property of the PN junctions, a current must flow through the diodes DS. To this end, during test operation, a connecting point S on the substrate of the sensor 3 is connected to ground GND by a resistor RC and a switch K1 by closing the switch K1. The resistor RC is significantly smaller than a resistor RP, which is arranged between the connecting point S and the supply voltage +Vcc. The resistor RP is also referred to as polarization resistor and has approximately ten times the value of the resistor RC. A capacitor C is arranged in parallel to the resistor RP, which ensures that the impedance of the substrate connecting point S to the ground GND for alternating voltages is set to a small enough level such that the substrate of the sensor 3 can also be used as a shielding to improve the electromagnetic compatibility. In the event of the switch K1 being closed for a test operation by the microcontroller 5 with the aid of a control signal CS, a current flows through the diodes DS and the resistor RC. A forward voltage is produced here between the reference voltage +VR and the substrate terminal S, where the forward voltage is indirectly measured by the A/D converter 4 at its input VA. Alternatively to the described indirect measurement of the forward voltage, it would naturally also be possible to directly detect the forward voltage, with a suitable embodiment of the sensor 3 and circuitry of the A/D converter 4.

The forward voltage of the diode DS is mainly dependent on two influencing factors, i.e., the temperature and the condition of the materials of the sensor 3, which can be changed for instance by chemical contamination. With a calibration of the measuring transducer 1, the forward voltage is measured to determine its temperature dependency for different temperatures and is stored in an EEPROM of the microcontroller 5 as a characteristic curve with the temperature as a characteristic curve parameter. As a result of the temperature behavior thus detected, the PN junction, which is symbolized by the diodes DS, can assume the function of a calibrated temperature sensor. To diagnose the temperature sensor TS, the temperature-dependent forward voltage of the diodes DS which is determined during test operation, is used to determine a comparison value for the temperature determined in real-time during normal operation using the temperature sensor TS. With deviations between the comparison value and the temperature determined with the aid of the temperature sensor TS, an error is detected and, with the aid of the microcontroller 5, an error message is output to the output FB and thus over the field bus 2, so that suitable measures for eliminating the error can be introduced. The deviations can be caused both by a contamination of the substrate of the sensor 3 and also by errors in the temperature sensor TS, such as due to a line interruption.

During normal operation, the switch K1 is opened by outputting a corresponding control signal CS. The substrate of the sensor 3 is applied to a potential across the resistor RP, the potential is higher than the reference voltage +VR, which is applied to the connecting point V+ of the sensor 3. The PN junctions symbolized with the diodes DS between the substrate and the electrical elements, i.e., the resistors R1 . . . R4, are thus blocked. No current therefore flows from the connecting point S into the measuring bridges formed with the resistors R1 . . . R4 and the electronic elements are electrically separated from the substrate of the sensor 3 by the PN junctions. As a result, an uncorrupted measurement of the pressure during normal operation is enabled.

Means are used advantageously predominantly for monitoring purposes, which are already present in a control and evaluation facility of a pressure measuring transducer. Only the resistor RC, the switch K1 and program sections of the microcontroller 5, which are suited to implementing a method for monitoring the condition of the sensor 3, have to be added. The new monitoring method, which enables a group diagnosis of the sensor 3, which contains a statement relating to the correctness of the measured sensor temperature and to the condition of the sensor materials, is therefore associated with a comparatively small additional outlay relative to conventional measuring transducers.

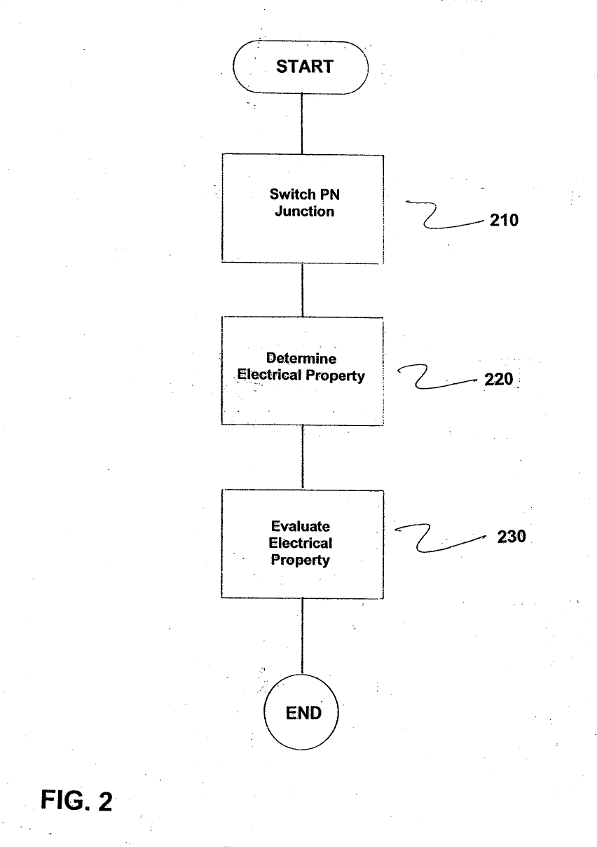

FIG. 2 is a flow chart of the a method for monitoring a condition of a sensor for detecting one of a physical and a chemical variable and for generating a measuring signal in a measuring transducer for process instrumentation having a control and evaluation unit for determining and outputting a measured value of one of the physical and chemical variable as a function of the measuring signal. Here, the sensor includes at least one electrical element embedded in a substrate comprising semi-conductive material and being electrically separated therefrom during normal operation by a blocked PN junction. The method comprises switching the PN junction in a forward direction during test operation, as indicated in step 210. Next, an electrical property of the PN junction is determined, as indicated in step 220. The electrical property is then evaluated to monitor the condition of the sensor, as indicated in step 230.

Thus, while there are shown, described and pointed out fundamental novel features of the invention as applied to preferred embodiments thereof, it will be understood that various omissions and substitutions and changes in the form and details of the illustrated apparatus, and in its operation, may be made by those skilled in the art without departing from the spirit of the invention. Moreover, it should be recognized that structures shown and/or described in connection with any disclosed form or embodiment of the invention may be incorporated in any other disclosed or described or suggested form or embodiment as a general matter of design choice.

1.-5. (canceled)

6. A measuring transducer for process instrumentation, comprising:
a sensor configured to detect one of a physical and a chemical variable and to generate a measuring signal; and
a control and evaluation unit configured to determine and output a measured value of one of the physical and the chemical variable as a function of the measuring signal;
wherein the sensor comprises at least one electrical element embedded into a substrate comprising semi-conductive material and is electrically separated therefrom during normal operating by a blocked PN junction; and
monitoring means for monitoring the status of the sensor, the monitoring means being configured to switch the PN junction during a test operation in a conducting direction and being configured to determine an electrical property of the PN junction and evaluate the PN junction to monitor a state of the sensor.

7. The measuring transducer as claimed in claim 6, further comprising:
a temperature sensor configured to detect the substrate temperature;
wherein the electrical property of the PN junction is temperature-dependent; and
wherein the monitoring means are configured to determine a first value of the temperature based on the electrical property and compare the first value with a second value which is determined with the temperature sensor.

8. The measuring transducer as claimed in claim 6, wherein the electrical property of the PN junction is a forward voltage of the PN junction in the conducting direction.

9. The measuring transducer as claimed in claim 7, wherein the electrical property of the PN junction is a forward voltage of the PN junction in the conducting direction.

10. The measuring transducer as claimed in claim 6, wherein the monitoring means for monitoring the condition are arranged at least partially in the control and evaluation unit.

11. A method for monitoring a condition of a sensor, the sensor configured for detecting one of a physical and a chemical variable and for generating a measuring signal, the sensor being arranged in a measuring transducer for process instrumentation having a control and evaluation unit for determining and outputting a measured value of one of the physical and the chemical variable as a function of the measuring signal, the sensor having at least one electrical element embedded in a substrate comprising semi-conductive material and being electrically separated therefrom during normal operation by a blocked PN junction, the method comprising the steps of:
switching the PN junction in a forward direction during test operation;
determining an electrical property of the PN junction; and
evaluating the electrical property to monitor a condition of the sensor.

12. The method of claim 11, wherein the electrical property of the PN junction is a forward voltage of the PN junction in the conducting direction.

13. The method of claim 11, wherein the measuring transducer further includes a temperature sensor configured to detect the substrate temperature, the electrical property of the PN junction is temperature dependent, and the step of evaluating includes determining a first value of the temperature based on the electrical property of the PN junction and comparing the first value to a second value determined with the temperature sensor.
